(19) United States
(12) Patent Application Publication
(10) Pub. No.: US 2025/0072035 A1
(43) Pub. Date: Feb. 27, 2025

(54) SEMICONDUCTOR DEVICE AND METHOD FOR FABRICATING THE SAME

(71) Applicant: UNITED MICROELECTRONICS CORP., Hsin-Chu City (TW)

(72) Inventors: Shin-Hung Li, Nantou County (TW); Cheng-Yu Ho, Hsinchu County (TW)

(73) Assignee: UNITED MICROELECTRONICS CORP., Hsin-Chu City (TW)

(21) Appl. No.: 18/369,209

(22) Filed: Sep. 18, 2023

(30) Foreign Application Priority Data
Aug. 23, 2023 (CN) 202311068153.5

(51) Int. Cl. H01L 29/78; H01L 29/06; H01L 29/66

(52) U.S. Cl. CPC H01L 29/7833; H01L 29/0603; H01L 29/6659

(57) ABSTRACT

A semiconductor device includes a first oxide layer and a gate structure. The first oxide layer is disposed on a substrate. The gate structure is disposed on the first oxide layer. The gate structure includes a gate and a spacer surrounding the gate. The first oxide layer includes an exposed segment not covered by the gate structure. A thickness of the first oxide layer right below the gate is fixed, and the thickness of the first oxide layer right below the gate is greater than a thickness of the exposed segment.

### BACKGROUND OF THE INVENTION

### 1. Field of the Invention

The present disclosure relates to the field of semiconductor devices, and more particularly, to a semiconductor device having an oxide layer with an asymmetric profile and a method for fabricating the same.

### 2. Description of the Prior Art

In the manufacturing of medium and high voltage integrated circuits, double-diffusion drain metal oxide semiconductor (DDDMOS) is often used to provide large output current. However, when the operating voltage is high, the DDDMOS is prone to generate the phenomenon of gate induced drain leakage (GIDL). As a result, the application of DDDMOS is greatly limited.

Therefore, how to improve the structure of DDDMOS and method for fabricating the same to reduce the probability of GIDL has become an important issue for the relevant industry.

### SUMMARY OF THE INVENTION

According to one aspect of the present disclosure, a semiconductor device includes a first oxide layer and a gate structure. The first oxide layer is disposed on a substrate. The gate structure is disposed on the first oxide layer. The gate structure includes a gate and a spacer surrounding the gate. The first oxide layer includes an exposed segment not covered by the gate structure. A thickness of the first oxide layer right below the gate is fixed, and the thickness of the first oxide layer right below the gate is greater than a thickness of the exposed segment.

According to another aspect of the present disclosure, a method for fabricating a semiconductor device is disclosed. The method includes steps as follows. A thermal oxidation process is performed to form an oxide layer on a substrate, wherein the oxide layer includes a first oxide layer and a second oxide layer, and a thickness of the first oxide layer is greater than a thickness of the second oxide layer. A gate structure is formed on the oxide layer, wherein the gate structure partially covers the first oxide layer, so that the first oxide layer includes an exposed segment not covered by the gate structure. A portion of the exposed segment is removed, so that a thickness of the exposed segment is less than a thickness of a portion of the first oxide layer other than the exposed segment.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1, FIG. 2, FIG. 3, FIG. 4, FIG. 5 and FIG. 6 are schematic cross-sectional views showing steps of a method for fabricating a semiconductor device according to one embodiment of the present disclosure.

FIG. 7 is a schematic cross-sectional view of a semiconductor device according to another embodiment of the present disclosure.

### DETAILED DESCRIPTION

In the following detailed description of the embodiments, reference is made to the accompanying drawings which form a part thereof, and in which is shown by way of illustration specific embodiments in which the disclosure may be practiced. In this regard, directional terminology, such as up, down, left, right, front, back, bottom or top is used with reference to the orientation of the Figure(s) being described. The elements of the present disclosure can be positioned in a number of different orientations. As such, the directional terminology is used for purposes of illustration and is in no way limiting. In addition, identical numeral references or similar numeral references are used for identical elements or similar elements in the following embodiments.

Hereinafter, for the description of “the first feature is formed on or above the second feature”, it may refer that “the first feature is in contact with the second feature directly”, or it may refer that “there is another feature between the first feature and the second feature”, such that the first feature is not in contact with the second feature directly.

It is understood that, although the terms first, second, etc. may be used herein to describe various elements, regions, layers and/or sections, these elements, regions, layers and/or sections should not be limited by these terms. These terms may be only used to distinguish one element, region, layer and/or section from another element, region, layer and/or section. Terms such as “first,” “second,” and other numerical terms when used herein do not imply a sequence or order unless clearly indicated by the context. Thus, a first element, region, layer and/or section discussed below could be termed a second element, region, layer and/or section without departing from the teachings of the embodiments. The terms used in the claims may not be identical with the terms used in the specification, but may be used according to the order of the elements claimed in the claims.

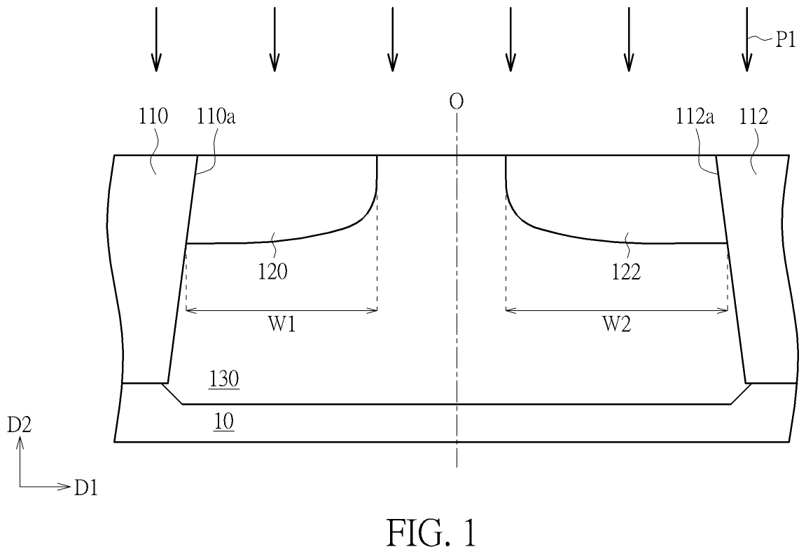

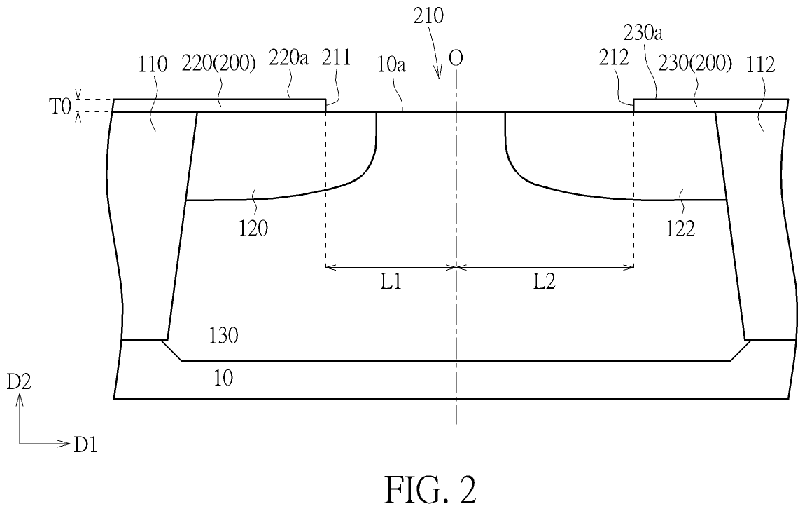

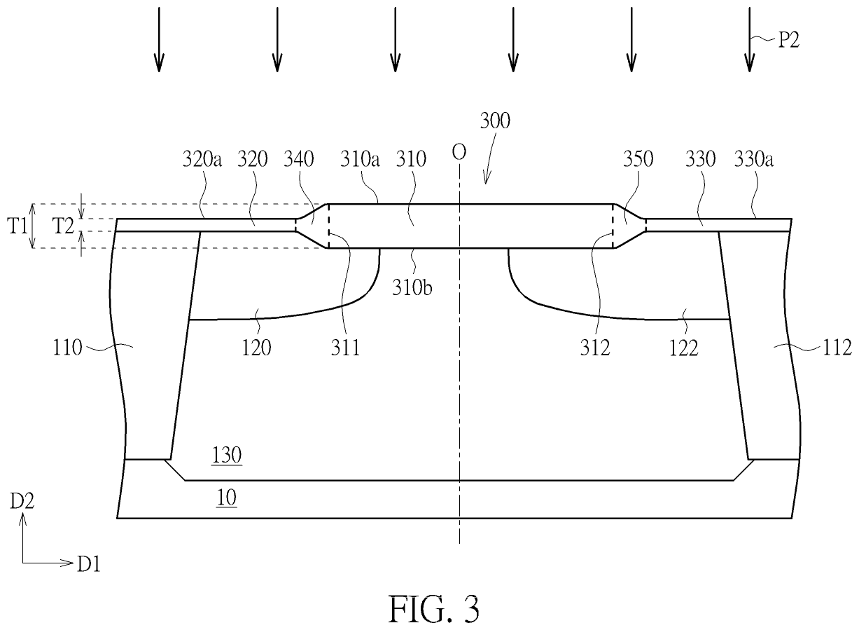

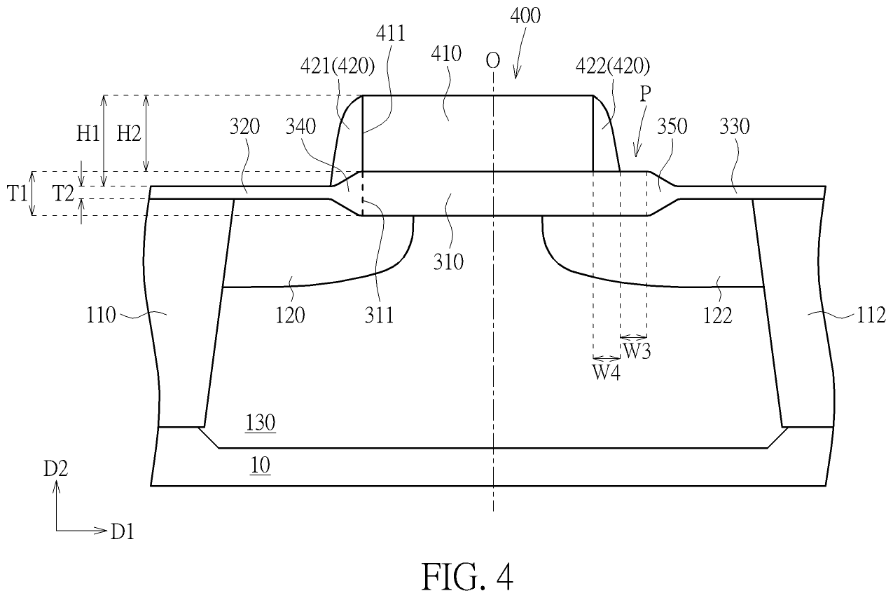

Please refer to FIG. 1 to FIG. 6, which are schematic cross-sectional views showing steps of a method for fabricating a semiconductor device according to one embodiment of the present disclosure. As shown in FIG. 1, a substrate 10 is provided first. The substrate 10 may be a silicon substrate, an epitaxial silicon substrate, a silicon carbide substrate or a silicon on insulator (SOI) substrate. Next, at least one shallow trench isolation (STI) is formed in the substrate 10 to surround each active region. For example, the two insulating structures 110 and 112 shown in FIG. 1 may be a left portion and a right portion of a shallow trench isolation, and the region between the two insulating structures 110 and 112 may be an active region. Materials of the insulating structures 110 and 112 may include silicon dioxide. Next, a first ion implantation process P1 is performed one or a plurality of times to form a well region 130 in the substrate 10 and to form a first light doped drain region 120 and a second light doped drain region 122 separated from each other in the substrate 10. The conductivity types of the first light doped drain region 120 and the second light doped drain region 122 are the same, and the conductivity type of the well region 130 is different from the conductivity types of the first light doped drain region 120 and the second light doped drain region 122. For example, when the well region 130 is an N-type well region, the well region 130 may be doped with N-type dopants, such as arsenic, phosphorus, etc. In this case, the first light doped drain region 120 and the second light doped drain region 122 may be doped with P-type dopants, such as boron, indium, etc. For another example, when the well region 130 is a P-type well region, the well region 130 may be doped with P-type dopants, such as boron, indium, etc. In this case, the first light doped drain region 120 and the second light doped drain region 120 may be doped with N-type dopants, such as arsenic, phosphorus, etc.

The first light doped drain region 120 is adjacent to the insulating structure 110 and contacts the insulating structure 110 directly. The second light doped drain region 122 is adjacent to the insulating structure 112 and contacts the insulating structure 112 directly. The width W2 of the second light doped drain region 122 is greater than the width W1 of the first light doped drain region 120. Specifically, the insulating structures 110 and 112 define a center line O, and the profiles of the first light doped drain region 120 and the second light doped drain region 122 are asymmetrically with respect to the center line O. The center line O may be a line connecting all midpoints of the inner surface 110a of the insulating structure 110 and the inner surface 112a of the insulating structure 112 in the horizontal direction D1. The width W1 and the width W2 may be the maximum width of the first light doped drain region 120 and the second light doped drain region 122 in the horizontal direction D1, respectively.

Next, as shown in FIG. 2, a patterned material layer 200 is formed on the substrate 10, wherein the patterned material layer 200 has an opening region 210. For example, a material layer (not shown) can be formed on the substrate 10 first, then a hard mask (not shown) can be formed on the material layer, and a portion of the material layer can be removed by semiconductor processes, such as lithography process and etching process, to obtain the patterned material layer 200 with the opening region 210. The material of the patterned material layer 200 may include a nitride such as silicon nitride, but not limited thereto. Materials with an oxidation rate less than that of the material of substrate 10 can be used as the material of patterned material layer 200.

Specifically, the patterned material layer 200 includes a first material portion 220 and a second material portion 230. The first material portion 220, the opening region 210 and the second material portion 230 are sequentially disposed on the substrate 10 along the horizontal direction D1. The first material portion 220 covers the insulating structure 110 and a portion of the first light doped drain region 120. The second material portion 230 covers the insulating structure 112 and a portion of the second light doped drain region 122.

The opening region 210 is located between the first material portion 220 and the second material portion 230, and exposes the rest portion of the first light doped drain region 120 and the rest portion of the second light doped drain region 122. The distance L1 between the left edge 211 of the opening region 210 and the center line O in the horizontal direction D1 is less than the distance L2 between the right edge 212 of the opening region 210 and the center line in the horizontal direction D1. In other words, the disposed position of the opening region 210 is asymmetrical with respect to the center line O.

Next, as shown in FIG. 3, a thermal oxidation process P2 is performed to form an oxide layer 300 on the substrate 10. The oxide layer 300 includes a first oxide layer 310 and two second oxide layers 320 and 330. The thickness T1 of the first oxide layer 310 is greater than the thickness T2 of each of the second oxide layers 320 and 330. The first oxide layer 310 corresponds to the opening region 210, and the two second oxide layers 320 and 330 are formed by oxidizing the patterned material layer 200. For example, the thermal oxidation process P2 can be performed in an oxygen-containing environment. The oxygen-containing environment can be achieved by introducing oxygen or oxygen-containing gas (such as water vapor) into the process chamber of the thermal oxidation process P2. According to an embodiment of the present disclosure, the thermal oxidation process P2 may include in-situ steam generation (ISSG) oxidation process, wet furnace oxidation process, or dry furnace oxidation process, but not limited thereto.

In the thermal oxidation process P2, the surface layer (not labeled) of the substrate 10 corresponding to the opening region 210 is oxidized to form the first oxide layer 310, the first material portion 220 of the patterned material layer 200 is oxidized to form the second oxide layer 320, and the second material portion 230 of the patterned material layer 200 is oxidized to form the second oxide layer 330. Since the disposed position of the opening region 210 is asymmetrical with respect to the center line O, the disposed position of the first oxide layer 310 is also asymmetrical with respect to the center line O.

Since the oxidation rate of the substrate 10 is greater than that of the patterned material layer 200, the thickness T1 of the first oxide layer 310 is greater than the thickness T2 of each of the second oxide layers 320 and 330. According to an embodiment of the present disclosure, a ratio of the oxidation rate of the substrate 10 to the oxidation rate of the patterned material layer 200 is greater than 2 (i.e., the oxidation selectivity of the substrate 10 with respective to the patterned material layer 200 is greater than 2), for example, can be equal to 10. According to an embodiment of the present disclosure, the thickness T1 of the first oxide layer 310 may be greater than 300 angstroms, and the thickness T2 of each of the second oxide layers 320 and 330 may be greater than 0 angstroms and less than or equal to 300 angstroms. However, the present disclosure is not limited thereto, the thickness T1 of the first oxide layer 310 and the thickness T2 of each of the second oxide layers 320 and 330 can be adjusted by selecting materials having an appropriate oxidation selectivity with respective to the substrate 10 as the material of the patterned material layer 200, by controlling the thickness T0 (see FIG. 2) of the patterned material layer 200, and by controlling the parameters of the thermal oxidation process P2.

During the thermal oxidation process P2, the oxygen atoms of the oxygen-containing gas enter into the substrate 10 and combine with the silicon of the substrate 10 to form silicon oxide. After the thermal oxidation process P2, the top surface 310a of the first oxide layer 310 is slightly higher than the top surface 10a (see FIG. 2) of the substrate 10 before performing the thermal oxidation process P2, and the bottom surface 310b of the first oxide layer 310 is slightly lower than the top surface 10a (see FIG. 2) of the substrate 10 before performing the thermal oxidation process P2. During the thermal oxidation process P2, the oxygen atoms of the oxygen-containing gas can enter into the patterned material layer 200 to replace other atoms of the patterned material layer 200, and the top surface 320a of the second oxide layer 320 and the top surface 330a of the second oxide layer 330 may be slightly higher, slightly lower, or substantially aligned with the top surface 220a (see FIG. 2) of the first material portion 220 and the top surface 230a (see FIG. 2) of the second material portion 230 before performing the thermal oxidation process P2, which is determined depending on the volumes of the oxygen atoms and the aforementioned other atoms. According to an embodiment of the present disclosure, the patterned material layer 200 can be silicon nitride. After the thermal oxidation process P2, the nitrogen atoms of the silicon nitride can be completely or partially replaced by the oxygen atoms. When the nitrogen atoms of the silicon nitride are completely replaced by the oxygen atoms, the silicon nitride can be converted into the silicon oxide. In this case, the material of each of the second oxide layers 320 and 330 and the material the first oxide layer 310 are the same, all of which are silicon oxide. When the nitrogen atoms of the silicon nitride are partially replaced by the oxygen atoms, the silicon nitride can be converted into silicon oxynitride. In this case, the material of each of the second oxide layers 320 and 330 is different from the material of the first oxide layer 310. Herein, the material of each of the second oxide layers 320 and 330 is exemplary the same as that of the first oxide layer 310a. Therefore, difference regions (such as the first oxide layer 310, the second oxide layers 320 and 330, and the bird's beak structures 340 and 350) are divided by dashed lines.

Since the oxidation rate of the substrate 10 is different from the oxidation rate of the patterned material layer 200, the bird's beak structure 340 is formed at the position where the first oxide layer 310 and the second oxide layer 320 are connected, and the bird's beak structure 350 is formed at the position where the first oxide layer 310 and the second oxide layer 330 are connected. In other words, the oxide layer 300 further includes two bird's beak structures 340 and 350 extending integrally from the two sides 311 and 312 of the first oxide layer 310, respectively. The thickness (not labeled) of the bird's beak structure 340 varies gradually (herein, decreases gradually) from the first oxide layer 310 to the second oxide layer 320, and the thickness (not labeled) of the bird's beak structure 350 varies gradually (herein, decreases gradually) from the first oxide layer 310 to the second oxide layer 330. According to an embodiment of the present disclosure, the materials of the first oxide layer 310, the second oxide layer 320, 330, and the bird's beak structures 340 and 350 are all silicon oxide. In addition, at this stage, the first oxide layer 310 refers to the portion of the oxide layer 300 with a thickness T1 which is uniform or substantially fixed, each of the second oxide layers 320 and 330 refers to the portion of the oxide layer 300 with a thickness T2 which is uniform or substantially fixed, the bird's beak structure 340 refers to the portion between the first oxide layer 310 and the second oxide layer 320 and having a thickness varying gradually, and the bird's beak structure 350 refer to a portion between the first oxide layer 310 and the second oxide layer 330 and having a thickness varying gradually, as indicated by the dashed lines in FIG. 3. That is, at this stage, the first oxide layer 310 has the thickness T1 which is uniform or substantially fixed, and each of the second oxide layers 320 and 330 has the thickness T2 which is uniform or substantially fixed.

Next, as shown in FIG. 4, a gate structure 400 is formed on the oxide layer 300, wherein the gate structure 400 partially covers the first oxide layer 310, so that the first oxide layer 310 includes an exposed segment P not covered by the gate structure 400. In addition, the second light doped drain region 122 is located below the exposed segment P. Forming the gate structure 400 on the oxide layer 300 includes forming a gate 410 on the oxide layer 300 and forming a spacer 420 surrounding the gate 410. For example, a deposition process can be performed to deposit a gate material on the oxide layer 300, and then a patterning process can be performed to remove a portion of the gate material to form the gate 410. The material of the gate 410 may include non-metallic conductive materials, such as polycrystalline silicon. Next, the spacer 420 is formed to surround the gate 410. The material of the spacer 420 may include oxides and/or nitrides, such as silicon dioxide, silicon nitride, silicon oxynitride or silicon carbonitride.

As shown in FIG. 4, the gate 410 is disposed on the first oxide layer 310, and the side 311 of the first oxide layer 310 away from the exposed segment P is aligned with the side surface 411 of the gate 410. The spacer 420 has two sidewalls 421 and 422 opposite to each other. The sidewall 421 is disposed on the bird's beak structure 340, and the sidewall 422 is disposed on the first oxide layer 310. Because the thickness of the bird's beak structure 340 varies gradually from the first oxide layer 310 to the second oxide layer 320, the maximum height H1 of the sidewall 421 is different from the maximum height H2 of the sidewall 422. Herein, the maximum height H1 of the sidewall 421 is greater than the maximum height H2 of the sidewall 422. That is, the profile of the sidewall 421 and the profile of the sidewall 422 are asymmetrical relative to the center line O. The sidewall 422 is adjacent to the exposed segment P, and the ratio of the width W3 of the exposed segment P to the width W4 of the sidewall 422 (W3/W4) may be greater than or equal to 2. For example, the ratio of the width W3 to the width W4 may be 2 to 3. The aforementioned width W4 may be the maximum width of the sidewall 422 in the horizontal direction D1.

The portion of the first oxide layer 310 right below the gate 410 has a uniform thickness T1. That is, the thickness T1 of the first oxide layer 310 right below the gate 410 is fixed. The aforementioned “the thickness T1 of the first oxide layer 310 right below the gate 410 is fixed” refers that the thickness T1 of the first oxide layer 310 right below the gate 410 is substantially fixed, i.e., the thicknesses T1 at different positions of the first oxide layer 310 right below the gate 410 are substantially the same, but there may be a slight error due to process factors or other factors. The error of the thickness T1 at any of the positions of the first oxide layer 310 right below the gate 410 relative to the predetermined thickness T1 may be, for example, less than or equal to 20%.

Among the two bird's beak structures 340 and 350, the bird's beak structure 340 is completely covered by the gate structure 400 and located below the sidewall 421 of the spacer 420, the bird's beak structure 350 is not covered by the gate structure 400 and located outside another sidewall 422 of the spacer 420, and the bird's beak structure 350 extends integrally from the segment P of the first oxide layer 310. As shown in FIG. 4, the two bird's beak structures 340 and 350 and the gate 410 do not overlap in the vertical direction D2.

Next, as shown in FIG. 5, one or more cleaning steps can be performed to completely remove the second oxide layers 320 and 330, so that the regions of the substrate 10 originally covered by the second oxide layers 320 and 330 are exposed. During the process of removing the second oxide layers 320 and 330, a portion of the exposed segment P is removed simultaneously, so that the thickness T3 of the exposed segment P is less than the thickness T1 of the portion of the first oxide layer 310 other than the exposed segment P. The portion of the first oxide layer 310 other than the exposed segment P includes the portion of the first oxide layer 310 right below the gate 410 and the portion of the first oxide layer 310 right below the sidewall 422 of the spacer 420. The thickness difference between the thickness T1 and the thickness T3 (i.e., T1−T3) is substantially equal to the thickness T2 of each of the second oxide layers 320 and 330. In other words, the first oxide layer 310 has an asymmetric profile.

Next, please continue to refer to FIG. 5, a second ion implantation process P3 is performed to form a source region 140 and a drain region 142 in the substrate 10 corresponding to the regions where the second oxide layers 320 and 330 are originally disposed, wherein the drain region 142 is adjacent to the exposed segment P. The first light doped drain region 120 surrounds the source region 140, and the second light doped drain region 122 surrounds the drain region 142. The conductivity types of the source region 140 and the drain region 142 are the same as that of the first light doped drain region 120 and the second light doped drain region 122, but the doping concentrations of the source region 140 and the drain region 142 are higher than that of the first light doped drain region 120 and the second light doped drain region 122. In other embodiments, the second ion implantation process P3 can be performed first, and then the second oxide layers 320 and 330 are removed, so that the second oxide layers 320 and 330 can be used to protect the top surface 10a of the substrate 10 when performing the second ion implantation process P3.

Next, as shown in FIG. 6, a self-aligned silicide process can be performed to form silicides 510 and 520 on the source region 140 and the drain region 142, respectively. For example, a metal layer (not shown) may be formed first to cover the source region 140 and the drain region 142, and then a thermal process is performed, such that the silicon in the source region 140 and the drain region 142 that directly contacts the metal layer reacts with the metal of the metal layer to form the silicides 510 and 520. How to form the silicides 510 and 520 is well known in the art and is omitted herein.

Although not shown, the non-metallic conductive material of the gate 410 may be replaced with a single-layer structure or a multi-layer structure including metallic conductive material by a replacement metal gate (RMG) process according to actual needs. The aforementioned single-layer structure may only include a low-resistance metal layer, and a material of the low-resistance metal layer may include, for example, copper (Cu), aluminum (Al), tungsten (W), titanium aluminum alloy (TiAl), cobalt tungsten phosphide (CoWP) or a combination thereof. The aforementioned multi-layer structure may be formed by a low-resistance metal layer and a high dielectric constant (high-k) dielectric layer and/or a barrier layer and/or a work function metal layer. The replacement metal gate process is well known in the art and is omitted herein.

The aforementioned film layers, such as the patterned material layer 200, the gate 400 and the spacer 420, may be formed by any suitable methods. For example, the methods may be, but are not limited to, molecular-beam epitaxy (MBE), chemical vapor deposition (CVD), metal organic chemical vapor deposition (MOCVD), hydride vapor phase epitaxy (HVPE) and atomic layer deposition (ALD).

Please refer to FIG. 6, which shows a schematic cross-sectional view of a semiconductor device 1 according to an embodiment of the present disclosure. The semiconductor device 1 is a double-diffusion drain metal oxide semiconductor field effect transistor.

The semiconductor device 1 includes the substrate 10, the first oxide layer 310 and the gate structure 400. The first oxide layer 310 is disposed on the substrate 10, and the gate structure 400 is disposed on the first oxide layer 310. The gate structure 400 includes the gate 410 and the spacer 420. The spacer 420 surrounds the gate 410. The first oxide layer 310 includes the exposed segment P which is not covered by the gate structure 400. The thickness T1 of the first oxide layer 310 right below the gate 410 is fixed (i.e., substantially fixed), and the thickness T1 of the first oxide layer 310 right below the gate 410 is greater than the thickness T3 of the exposed segment P. With the exposed segment P, the first oxide layer 310 has an asymmetric profile, which is beneficial to increase the distance between the gate structure 400 and the drain region 142, and is beneficial to reduce the probability of GIDL, so that the semiconductor device 1 can withstand higher voltages and has the advantage of power saving. Accordingly, the application scope thereof can be broadened. For example, the semiconductor device 1 can be applied to display devices with always on display (AOD) function, or virtual reality (VR) devices or augmented reality (AR) devices that require low power consumption.

In the semiconductor device 1, the ratio of the width W3 of the exposed segment P to the width W4 of the sidewall 422 of the spacer 420 may be greater than or equal to 2. For example, the ratio of the width W3 to the width W4 may be 2 to 3.

In the semiconductor device 1, the side 311 of the first oxide layer 310 away from the exposed segment P is aligned with the side surface 411 of the gate 410. Thereby, the first oxide layer 310 right below the gate 410 has a uniform thickness, which is beneficial to improve the electrical performance of the semiconductor device 1.

The semiconductor device 1 further includes the insulating structures 110 and 112, the well region 130, the first light doped drain region 120, the second light doped drain region 122, the source region 140, the drain region 142, and the silicides 510 and 520. The well region 130 is formed in the substrate 10. The first light doped drain region 120 and the second light doped drain region 122 are formed in the substrate 10 and are located at two sides of the gate structure 400, respectively. The second light doped drain region 122 is located below the exposed segment P, and the width W2 of the second light doped drain region 122 is greater than the width W1 of the first light doped drain region 120. The source region 140 and the drain region 142 are located at two sides of the gate structure 400, respectively. The drain region 142 is adjacent to the exposed segment P. The first light doped drain region 120 surrounds the source region 140, and the second light doped drain region 122 surrounds the drain region 142.

The semiconductor device 1 further includes the two bird's beak structures 340 and 350 extending integrally from the two sides 311 and 312 of the first oxide layer 310, respectively. The two bird's beak structures 340 and 350 do not overlap with the gate 410 in the vertical direction D2. The bird's beak structure 340 is located below the sidewall 421 of the spacer 420, and the other bird's beak structure 350 is located outside another sidewall 422 of the spacer 420. Thereby, the bird's beak structures 340 and 350 with thickness varying gradually are not disposed right below the gate 410, which is beneficial to improve the electrical performance of the semiconductor device 1.

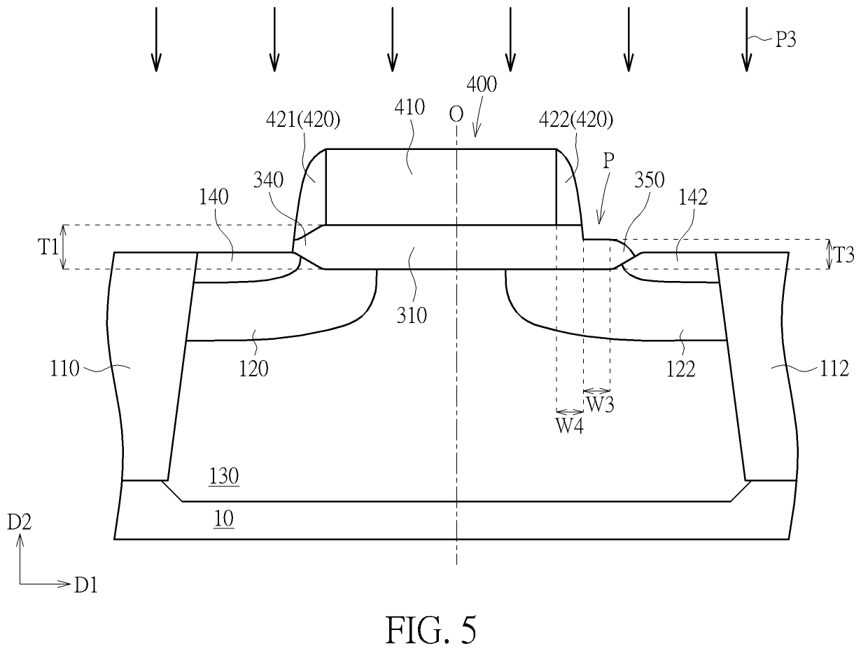

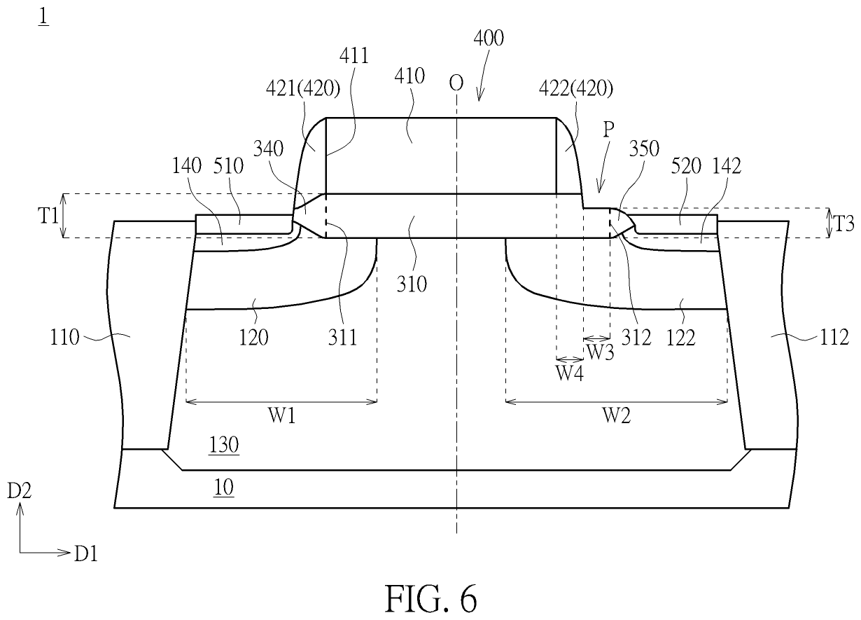

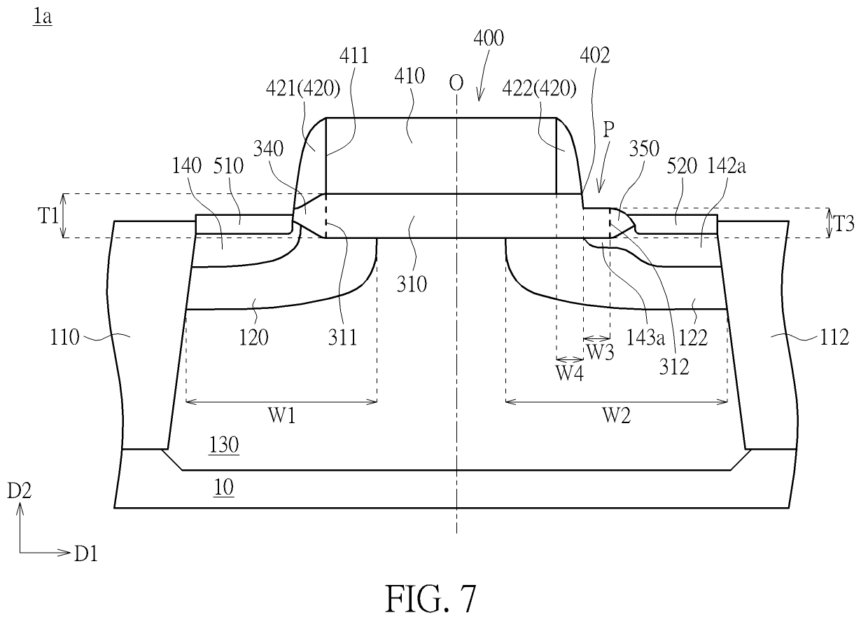

Please refer to FIG. 7, which is a schematic cross-sectional view of a semiconductor device 1a according to another embodiment of the present disclosure. The main difference between the semiconductor device 1a and the semiconductor device 1 is that when performing the second ion implantation process P3 (see FIG. 5), the implantation energy of the second ion implantation process P3 is adjusted, so that the drain region 142a can extend below the exposed segment P to form a drain extension 143a. Specifically, the implantation energy of the second ion implantation process P3 can be increased, so that ions can pass through the exposed segment P and enter into the portion of the substrate 10 below the exposed segment P. At the same time, the gate structure 400 blocks ions from entering into the portion of the substrate 10 below the gate structure 400. Therefore, a portion of the drain region 142a (i.e., the drain extension 143a) is located below the exposed segment P and aligned with the outer edge 402 of the gate structure 400. With the exposed segment P, the first oxide layer 310 has an asymmetric profile, which is beneficial to increase the distance between the gate structure 400 and the drain region 142a.

Compared with the prior art, the present disclosure provides a semiconductor device including a first oxide layer with an exposed segment not covered by a gate structure, which is beneficial to increase the distance between the gate structure and a drain region, and is beneficial to reduce the probability of GIDL. Therefore, the semiconductor device can withstand higher voltages and has the advantage of power saving, which is beneficial to broaden the application scope thereof.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor device, comprising:
a first oxide layer disposed on a substrate; and
a gate structure disposed on the first oxide layer, wherein the gate structure comprises a gate and a spacer surrounding the gate, the first oxide layer comprises an exposed segment not covered by the gate structure, a thickness of the first oxide layer right below the gate is fixed, and the thickness of the first oxide layer right below the gate is greater than a thickness of the exposed segment.

2. The semiconductor device of claim 1, further comprising:
a first light doped drain region and a second light doped drain region respectively located at two sides of the gate structure.

3. The semiconductor device of claim 2, wherein the second light doped drain region is located below the exposed segment, and a width of the second light doped drain region is greater than a width of the first light doped drain region.

4. The semiconductor device of claim 2, further comprising:
a source region and a drain region respectively located at the two sides of the gate structure, and the drain region is adjacent to the exposed segment.

5. The semiconductor device of claim 4, wherein a portion of the drain region is located below the exposed segment and is aligned with an outer edge of the gate structure.

6. The semiconductor device of claim 4, wherein the first light doped drain region surrounds the source region, and the second doped drain region surrounds the drain region.

7. The semiconductor device of claim 1, wherein a ratio of a width of the exposed segment to a width of a sidewall of the spacer is greater than or equal to 2.

8. The semiconductor device of claim 1, further comprising:
two bird's beak structures respectively extending integrally from two sides of the first oxide layer, and the two bird's beak structures do not overlap with the gate in a vertical direction.

9. The semiconductor device of claim 8, wherein one of the bird's beak structures is located below a sidewall of the spacer, and another one of the bird's beak structures is located outside another sidewall of the spacer.

10. The semiconductor device of claim 1, wherein a side of the first oxide layer away from the exposed segment is aligned with a side surface of the gate.

11. A method for fabricating a semiconductor device, comprising:
performing a thermal oxidation process to form an oxide layer on a substrate, wherein the oxide layer comprises a first oxide layer and a second oxide layer, and a thickness of the first oxide layer is greater than a thickness of the second oxide layer;
forming a gate structure on the oxide layer, wherein the gate structure partially covers the first oxide layer, so that the first oxide layer comprises an exposed segment not covered by the gate structure; and
removing a portion of the exposed segment, so that a thickness of the exposed segment is less than a thickness of a portion of the first oxide layer other than the exposed segment.

12. The method of claim 11, before performing the thermal oxidation process, the method further comprising:
forming a patterned material layer on the substrate, wherein the patterned material layer has an opening region, the first oxide layer corresponds to the opening region, and the second oxide layer is formed by oxidizing the patterned material layer.

13. The method of claim 12, before forming a patterned material layer, the method further comprising:
performing a first ion implantation process to form a first light doped drain region and a second light doped drain region separated from each other in the substrate.

14. The method of claim 13, wherein the second light doped drain region is located below the exposed segment, and a width of the second light doped drain region is greater than a width of the first light doped drain region.

15. The method of claim 14, further comprising:
removing the second oxide layer; and
performing a second ion implantation process to form a source region and a drain region in the substrate corresponding to the regions where the second oxide layers are originally disposed, wherein the drain region is adjacent to the exposed segment.

16. The method of claim 15, wherein a portion of the drain region is located below the exposed segment and is aligned with an outer edge of the gate structure.

17. The method of claim 15, wherein the first light doped drain region surrounds the source region, and the second doped drain region surrounds the drain region.

18. The method of claim 11, wherein forming the gate structure on the oxide layer comprises:
forming a gate on the oxide layer; and
forming a spacer surrounding the gate.

19. The method of claim 18, wherein a ratio of a width of the exposed segment to a width of a sidewall of the spacer is greater than or equal to 2.

20. The method of claim 18, wherein the oxide layer further comprises two bird's beak structures respectively extending integrally from two sides of the first oxide layer, and the two bird's beak structures do not overlap with the gate in a vertical direction.

21. The method of claim 20, wherein one of the bird's beak structures is located below a sidewall of the spacer, and another one of the bird's beak structures is located outside another sidewall of the spacer.

22. The method of claim 18, wherein a side of the first oxide layer away from the exposed segment is aligned with a side surface of the gate.
